(19) United States
(12) Patent Application Publication
(10) Pub. No.: US 2009/0190650 A1
(43) Pub. Date: Jul. 30, 2009

(54) DRIVING SIGNAL GENERATION CIRCUIT

(76) Inventors: Shih-Chung Huang, Taipei (TW); Leaf Chen, Taipei (TW)

Correspondence Address: NORTH AMERICA INTELLECTUAL PROPERTY CORPORATION, P.O. BOX 506, MERRIFIELD, VA, 22116, US

(21) Appl. No.: 12/252,367

(22) Filed: Oct. 16, 2008

(30) Foreign Application Priority Data
Jan. 30, 2008 (TW) 097103430

(51) Int. Cl. H03K 7/08

(52) U.S. Cl. 375/238

(57) ABSTRACT

A driving signal generation circuit including a transforming circuit and a phase split circuit is disclosed. The transforming circuit is utilized to generate a transformed signal by delaying a rising or falling edge of each pulse of a pulse-width-modulation signal. The phase split circuit generates first and second driving signals by respectively extracting each odd pulse and each even pulse of the transformed signal. Furthermore, disclosed is another driving signal generation circuit including a phase split circuit and a phase shift circuit. The phase split circuit generates first and second push-pull signals by respectively extracting each odd pulse and each even pulse of the pulse-width-modulation signal. The phase shift circuit generates a driving signal by delaying rising and falling edges of each pulse of the first or second push-pull signal.

### BACKGROUND OF THE INVENTION

1. Field of the Invention

The present invention relates to a driving signal generation circuit, and more particularly, to a driving signal generation circuit for providing push-pull related signals for driving electronic devices.

2. Description of the Prior Art

Along with the requirement of various driving signals for driving different electronic devices, the driving signal generation circuit has become an important front-end circuit of electronic devices and has a significant effect on the performance of electronic devices. For instance, in the operation of an electronic device driven by an AC signal, an inverter is required for converting a DC supply voltage into the AC signal with the aid of a plurality of driving signals. That is, a driving signal generation circuit is further required to provide the driving signals for the inverter. In other words, the driving signal generation circuit functions as an important front-end circuit for providing the driving signals so as to drive the inverter, regardless of a half-bridge inverter or a full-bridge inverter, for performing a DC-to-AC converting process.

Please refer to FIG. 1, which is a circuit diagram schematically showing a prior-art driving signal generation circuit 110. The driving signal generation circuit 110 is coupled to a full-bridge inverter 180. The full-bridge inverter 180 comprises four transistors 181-184. The transistors 181, 182 are P-channel metal oxide semiconductor (PMOS) field effect transistors, and the transistors 183, 184 are NMOS field effect transistors. The AC signal generated by the full-bridge inverter 180 is forwarded to a load 195 after going through the DC blocking operation of a block capacitor 191 and the AC transforming operation of a transformer 193. The driving signal generation circuit 110 includes a push-pull signal generator 120 and a signal processing circuit 130. The push-pull signal generator 120 is utilized for generating two push-pull signals Sa and Sb. The signal processing circuit 130 comprises six resistors 131-136, four diodes 151-154, and two couple capacitors 141, 142. The signal processing circuit 130 functions to generate four driving signals Sd1-Sd4 for driving the transistors 181-184 respectively based on the push-pull signals Sa and Sb.

Although the signal processing circuit 130 is composed of common used components as aforementioned, the resistor-capacitor circuit of the signal processing circuit 130 is likely to incur problems regarding initial value setting and circuit transient response. That is, after the signal processing circuit 130 is powered, the signal processing circuit 130 is not able to work properly, i.e. in a steady state, before going through a transient response time. Furthermore, since the signal processing circuit 130 makes use of resistors as buffer components for driving the full-bridge inverter 180, the driving ability of the full-bridge inverter 180 is then quite limited. Besides, the driving signals Sd1-Sd4 generated by the driving signal generation circuit 110 cannot drive the full-bridge inverter 180 to output an AC signal having exactly balanced positive and negative half-periods, especially during the transient response time. That is why the block capacitor 191 is required to be installed for performing a DC blocking operation on the AC signal for protecting the transformer 193 from being damaged by the DC component of the AC signal.

### SUMMARY OF THE INVENTION

In accordance with an embodiment of the present invention, a system for providing at least one driving signal is disclosed. The system comprises a driving signal generation circuit for receiving a pulse width modulation (PWM) signal. The driving signal generation circuit functions to generate a driving signal based on the PWM signal. The duty cycle of the driving signal is generated by means of firstly performing a phase shift operation and secondly performing a phase split operation regarding the PWM signal.

In accordance with another embodiment of the present invention, a system for providing at least one driving signal is disclosed. The system comprises a driving signal generation circuit for receiving a PWM signal. The driving signal generation circuit functions to generate a driving signal based on the PWM signal. The duty cycle of the driving signal is generated by means of firstly performing a phase split operation and secondly performing a phase shift operation regarding the PWM signal.

The present invention further discloses a driving signal generation circuit for providing at least one driving signal. The driving signal generation circuit comprises a transforming circuit and a phase split circuit. The transforming circuit is utilized for generating a transformed signal by essentially performing a phase shift operation on a PWM signal. The phase split circuit functions to generate a first driving signal and a second driving signal by respectively extracting a first pulse and a second pulse of the transformed signal.

Furthermore, the present invention discloses a driving signal generation circuit for providing at least one driving signal. The driving signal generation circuit comprises a phase split circuit and a transforming circuit. The phase split circuit is utilized for generating a push-pull signal by extracting a pulse of a PWM signal. The transforming circuit functions to generate a driving signal by essentially performing a phase shift operation on the push-pull signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram schematically showing a prior-art driving signal generation circuit.

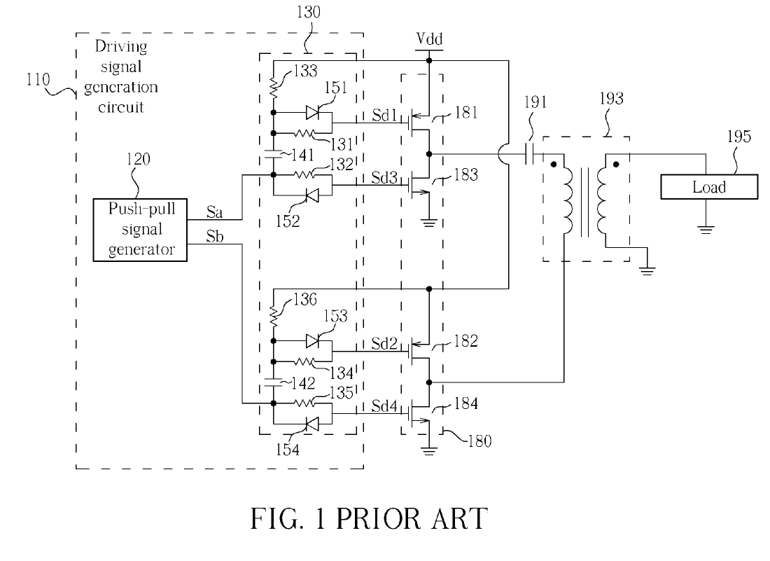

FIG. 2 is a circuit diagram schematically showing a driving signal generation circuit in accordance with a first embodiment of the present invention.

FIG. 3 shows the related signal waveforms regarding the operation of the driving signal generation circuit in FIG. 2, having time along the abscissa.

FIG. 4 is a circuit diagram schematically showing a driving signal generation circuit in accordance with a second embodiment of the present invention.

FIG. 5 shows the related signal waveforms regarding the operation of the driving signal generation circuit in FIG. 4, having time along the abscissa.

FIG. 6 is a circuit diagram schematically showing a driving signal generation circuit in accordance with a third embodiment of the present invention.

FIG. 7 shows the related signal waveforms regarding the operation of the driving signal generation circuit in FIG. 6, having time along the abscissa.

FIG. 8 is a schematic circuit diagram showing a first embodiment of the phase shift circuit.

FIG. 9 shows the related signal waveforms regarding the operation of the phase shift circuit in FIG. 8, having time along the abscissa.

FIG. 10 is a schematic circuit diagram showing a second embodiment of the phase shift circuit.

FIG. 11, which is a schematic circuit diagram showing a first embodiment of the phase split circuit.

FIG. 12 shows the related signal waveforms regarding the operation of the phase split circuit in FIG. 11, having time along the abscissa.

FIG. 13 is a schematic circuit diagram showing a second embodiment of the phase split circuit.

FIG. 14 is a schematic circuit diagram showing a third embodiment of the phase split circuit.

### DETAILED DESCRIPTION

Hereinafter, preferred embodiments of the present invention will be described in detail with reference to the accompanying drawings. Here, it is to be noted that the present invention is not limited thereto.

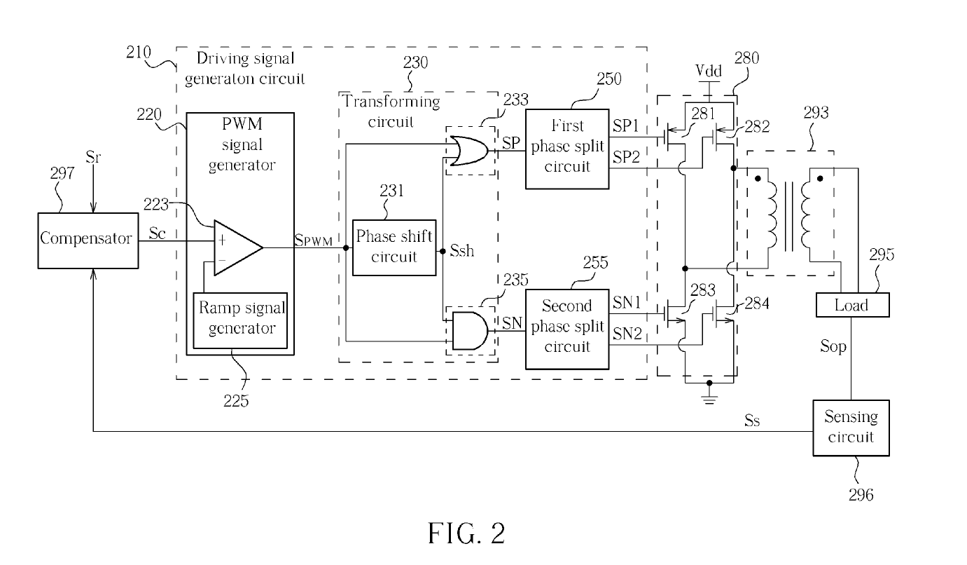

Please refer to FIG. 2, which is a circuit diagram schematically showing a driving signal generation circuit 210 in accordance with a first embodiment of the present invention. The driving signal generation circuit 210 is coupled to a network circuit comprising a full-bridge inverter 280, a transformer 293, a load 295, a sensing circuit 296 and a compensator 297. The full-bridge inverter 280 comprises four transistors 281-284. The transistors 281, 282 are PMOS field effect transistors, and the transistors 283, 284 are NMOS field effect transistors. The AC signal generated by the full-bridge inverter 280 is forwarded to the load 295 after going through an AC transforming operation of the transformer 293. The sensing circuit 296 generates a sensing signal Ss based on an operational signal Sop of the load 295. The compensator 297 performs a signal compensating process based on the sensing signal Ss and a reference signal Sr for generating a control signal Sc. The driving signal generation circuit 210 functions to generate a plurality of driving signals based on the control signal Sc.

In the embodiment shown in FIG. 2, the driving signal generation circuit 210 comprises a pulse width modulation (PWM) signal generator 220, a transforming circuit 230, a first phase split circuit 250, and a second phase split circuit 255. The PWM signal generator 220 generates a PWM signal S_{PWM} based on the control signal Sc. The PWM signal generator 220 comprises a comparator 223 and a ramp signal generator 225. The comparator 223 comprises a first input end for receiving the control signal Sc, a second input end coupled to the ramp signal generator 225, and an output end for outputting the PWM signal S_{PWM}. As shown in FIG. 2, the first input end of the comparator 223 is a positive input end and the second input end of the comparator 223 is a negative input end. In another embodiment, the first and second input ends of the comparator 223 can be the negative and positive input ends respectively. The ramp signal generator 225 is coupled to the second end of the comparator 223 and functions to provide a triangular wave signal or a sawtooth wave signal.

The transforming circuit 230 comprises a phase shift circuit 231, an OR gate 233 and an AND gate 235. The phase shift circuit 231 performs a phase shift operation on the rising and falling edges of each pulse of the PWM signal S_{PWM} for generating a phase shift signal Ssh. The OR gate 233 performs an OR operation on the PWM signal S_{PWM} and the phase shift signal Ssh for generating a first transformed signal SP. The AND gate 235 performs an AND operation on the PWM signal S_{PWM} and the phase shift signal Ssh for generating a second transformed signal SN.

The first phase split circuit 250 extracts each odd pulse of the first transformed signal SP for generating the driving signal SP1 and extracts each even pulse of the first transformed signal SP for generating the driving signal SP2. The second phase split circuit 255 extracts each odd pulse of the second transformed signal SN for generating the driving signal SN1 and extracts each even pulse of the second transformed signal SN for generating the driving signal SN2.

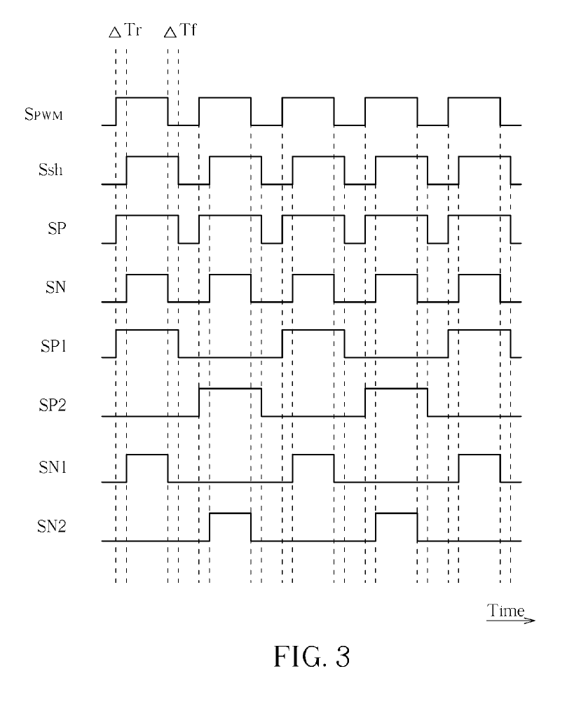

Please refer to FIG. 3, which shows the related signal waveforms regarding the operation of the driving signal generation circuit 210 in FIG. 2, having time along the abscissa. The signal waveforms in FIG. 3, from top to bottom, are the PWM signal S_{PWM}, the phase shift signal Ssh, the first transformed signal SP, the second transformed signal SN, the driving signal SP1, the driving signal SP2, the driving signal SN1, and the driving signal SN2. After the phase shift circuit 231 performs a phase shift operation on the PWM signal S_{PWM}, the phase shift signal Ssh is generated through delaying the rising and falling edges of each pulse of the PWM signal S_{PWM} by a first phase shift time ΔTr and a second phase shift time ΔTf respectively, as shown in FIG. 3.

After the OR gate 233 performs an OR operation on the PWM signal S_{PWM} and the phase shift signal Ssh, the first transformed signal SP is generated. As shown in FIG. 3, the first transformed signal SP is generated through delaying the falling edge of each pulse of the PWM signal S_{PWM} by the second phase shift time ΔTf while retaining the rising edge of each pulse of the PWM signal S_{PWM}. After the AND gate 235 performs an AND operation on the PWM signal S_{PWM} and the phase shift signal Ssh, the second transformed signal SN is generated. As shown in FIG. 3, the second transformed signal SN is generated through delaying the rising edge of each pulse of the PWM signal S_{PWM} by the first phase shift time ΔTr while retaining the falling edge of each pulse of the PWM signal S_{PWM}.

After the first phase split circuit 250 extracts each odd pulse of the first transformed signal SP, the driving signal SP1 having each pulse corresponding to one odd pulse of the first transformed signal SP is generated as shown in FIG. 3. After the first phase split circuit 250 extracts each even pulse of the first transformed signal SP, the driving signal SP2 having each pulse corresponding to one even pulse of the first transformed signal SP is generated as shown in FIG. 3. After the second phase split circuit 255 extracts each odd pulse of the second transformed signal SN, the driving signal SN1 having each pulse corresponding to one odd pulse of the second transformed signal SN is generated as shown in FIG. 3. After the second phase split circuit 255 extracts each even pulse of the second transformed signal SN, the driving signal SN2 having each pulse corresponding to one even pulse of the second transformed signal SN is generated as shown in FIG. 3.

As shown in FIG. 3, the duty cycle of the driving signal SP2 and the duty cycle of the driving signal SP1 are not overlapped. The duty cycle of the driving signal SN1 is substantially part of the duty cycle of the driving signal SP1. Also, the duty cycle of the driving signal SN2 and the duty cycle of the driving signal SN1 are not overlapped, and the duty cycle of the driving signal SN2 is substantially part of the duty cycle of the driving signal SP2. Furthermore, the lengths of the duty cycles of the driving signals SP1 and SP2 are the same, and the lengths of the duty cycles of the driving signals SN1 and SN2 are the same.

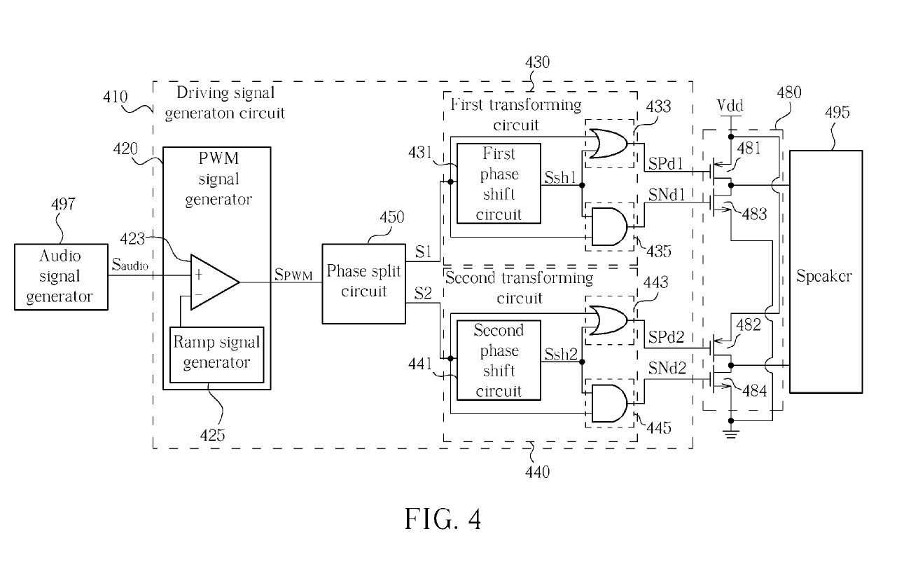

Please refer to FIG. 4, which is a circuit diagram schematically showing a driving signal generation circuit 410 in accordance with a second embodiment of the present invention. The driving signal generation circuit 410 is coupled to a network circuit comprising a full-bridge inverter 480, a speaker 495 and an audio signal generator 497. The full-bridge inverter 480 comprises four transistors 481-484. The transistors 481, 482 are PMOS field effect transistors, and the transistors 483, 484 are NMOS field effect transistors. The AC signal generated by the full-bridge inverter 480 is forwarded to the speaker 495 for generating an audio output. The audio signal generator 497 functions to provide an audio signal Saudio, and the driving signal generation circuit 410 generates a plurality of driving signals based on the audio signal Saudio.

The driving signal generation circuit 410 comprises a PWM signal generator 420, a phase split circuit 450, a first transforming circuit 430, and a second transforming circuit 440. The PWM signal generator 420 generates a PWM signal S_{PWM} based on the audio signal Saudio. The PWM signal generator 420 comprises a comparator 423 and a ramp signal generator 425. The comparator 423 comprises a first input end for receiving the audio signal Saudio, a second input end coupled to the ramp signal generator 425, and an output end for outputting the PWM signal S_{PWM}. As shown in FIG. 4, the first input end of the comparator 423 is a positive input end and the second input end of the comparator 423 is a negative input end. In another embodiment, the first and second input ends of the comparator 423 can be the negative and positive input ends respectively. The ramp signal generator 425 is coupled to the second end of the comparator 423 and functions to provide a triangular wave signal or a sawtooth wave signal. The phase split circuit 450 extracts each odd pulse of the PWM signal S_{PWM} for generating the first push-pull signal SI and extracts each even pulse of the PWM signal S_{PWM} for generating the second push-pull signal S2.

The first transforming circuit 430 comprises a first phase shift circuit 431, a first OR gate 433 and a first AND gate 435. The first phase shift circuit 431 generates a driving signal Ssh1 by performing a phase shift operation on the rising and falling edges of each pulse of the first push-pull signal S1. The first OR gate 433 generates a driving signal SPd1 by performing an OR operation on the first push-pull signal S1 and the driving signal Ssh1. The first AND gate 435 generates a driving signal SNd1 by performing an AND operation on the first push-pull signal S1 and the driving signal Ssh1.

The second transforming circuit 440 comprises a second phase shift circuit 441, a second OR gate 443 and a second AND gate 445. The second phase shift circuit 441 generates a driving signal Ssh2 by performing a phase shift operation on the rising and falling edges of each pulse of the second push-pull signal S2. The second OR gate 443 generates a driving signal SPd2 by performing an OR operation on the second push-pull signal S2 and the driving signal Ssh2. The second AND gate 445 generates a driving signal SNd2 by performing an AND operation on the second push-pull signal S2 and the driving signal Ssh2.

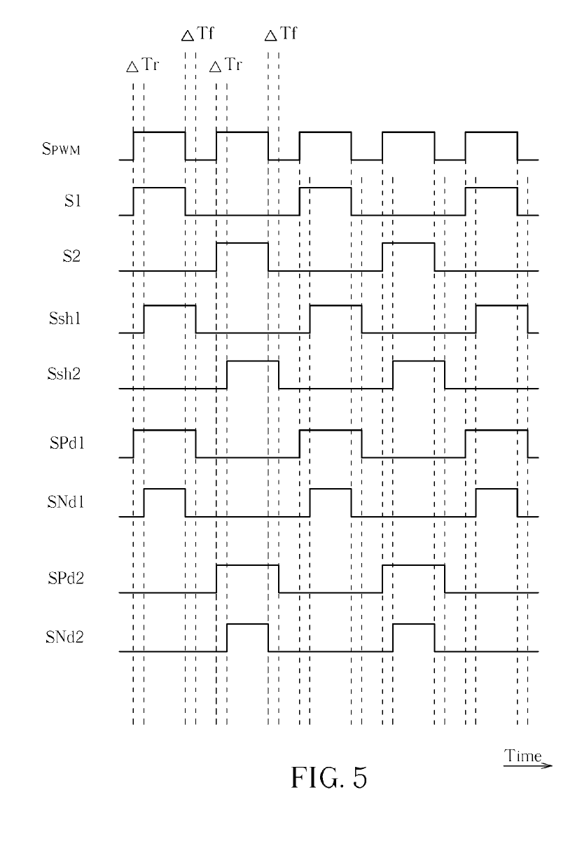

Please refer to FIG. 5, which shows the related signal waveforms regarding the operation of the driving signal generation circuit 410 in FIG. 4, having time along the abscissa. The signal waveforms in FIG. 5, from top to bottom, are the PWM signal S_{PWM}, the first push-pull signal SI, the second push-pull signal S2, the driving signal Ssh1, the driving signal Ssh2, the driving signal SPd1, the driving signal SNd1, the driving signal SPd2, and the driving signal SNd2. After the phase split circuit 450 performs a phase split operation on the PWM signal S_{PWM}, the first push-pull signal S1 and the second push-pull signal S2 are generated by respectively extracting the odd and even pulses of the PWM signal S_{PWM} as shown in FIG. 5.

After the first phase shift circuit 431 performs a phase shift operation on the first push-pull signal S1, the driving signal Ssh1 is generated through delaying the rising and falling edges of each pulse of the first push-pull signal S1 by a first phase shift time ΔTr and a second phase shift time ΔTf respectively as shown in FIG. 5. After the first OR gate 433 performs an OR operation on the first push-pull signal S1 and the driving signal Ssh1, the driving signal SPd1 is generated. As shown in FIG. 5, the driving signal SPd1 is generated through delaying the falling edge of each pulse of the first push-pull signal S1 by the second phase shift time ΔTf while retaining the rising edge of each pulse of the first push-pull signal S1. After the first AND gate 435 performs an AND operation on the first push-pull signal S1 and the driving signal Ssh1, the driving signal SNd1 is generated. As shown in FIG. 5, the driving signal SNd1 is generated through delaying the rising edge of each pulse of the first push-pull signal S1 by the first phase shift time ΔTr while retaining the falling edge of each pulse of the first push-pull signal S1.

After the second phase shift circuit 441 performs a phase shift operation on the second push-pull signal S2, the driving signal Ssh2 is generated through delaying the rising and falling edges of each pulse of the second push-pull signal S2 by the first phase shift time ΔTr and the second phase shift time ΔTf respectively as shown in FIG. 5. After the second OR gate 443 performs an OR operation on the second push-pull signal S2 and the driving signal Ssh2, the driving signal SPd2 is generated. As shown in FIG. 5, the driving signal SPd2 is generated through delaying the falling edge of each pulse of the second push-pull signal S2 by the second phase shift time ΔTf while retaining the rising edge of each pulse of the second push-pull signal S2. After the second AND gate 445 performs an AND operation on the second push-pull signal S2 and the driving signal Ssh2, the driving signal SNd2 is generated. As shown in FIG. 5, the driving signal SNd2 is generated through delaying the rising edge of each pulse of the second push-pull signal S2 by the first phase shift time ΔTr while retaining the falling edge of each pulse of the second push-pull signal S2.

As shown in FIG. 5, the duty cycle of the driving signal SNd1 is substantially part of the duty cycle of the driving signal SPd1. The duty cycle of the driving signal SPd2 and the duty cycle of the driving signal SPd1 are not overlapped. The duty cycle of the driving signal SNd2 is substantially part of the duty cycle of the driving signal SPd2. Furthermore, the lengths of the duty cycles of the driving signals SPd1 and SPd2 are the same, and the lengths of the duty cycles of the driving signals SNd1 and SNd2 are the same.

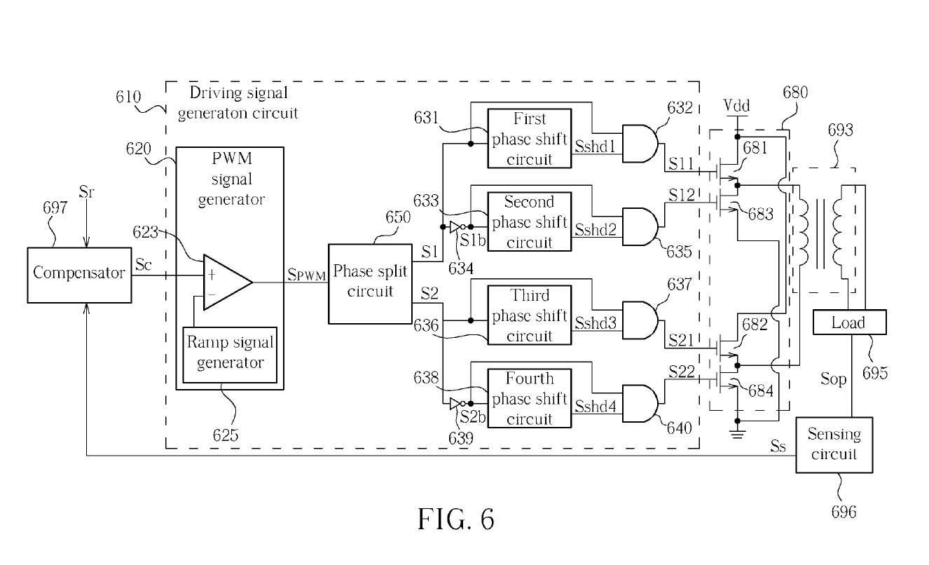

Please refer to FIG. 6, which is a circuit diagram schematically showing a driving signal generation circuit 610 in accordance with a third embodiment of the present invention. The driving signal generation circuit 610 is coupled to a network circuit comprising a full-bridge inverter 680, a transformer 693, a load 695, a sensing circuit 696 and a compensator 697. The full-bridge inverter 680 comprises four transistors 681-684. All the transistors 681-684 are NMOS field effect transistors. The AC signal generated by the full-bridge inverter 680 is forwarded to the load 695 after going through an AC transforming operation of the transformer 693. The sensing circuit 696 generates a sensing signal Ss based on an operational signal Sop of the load 695. The compensator 697 performs a signal compensating process based on the sensing signal Ss and a reference signal Sr for generating a control signal Sc. The driving signal generation circuit 610 is utilized for generating a plurality of driving signals based on the control signal Sc.

The driving signal generation circuit 610 comprises a PWM signal generator 620, a phase split circuit 650, a first phase shift circuit 631, a second phase shift circuit 633, a third phase shift circuit 636, a fourth phase shift circuit 638, a first inverter 634, a second inverter 639, a first AND gate 632, a second AND gate 635, a third AND gate 637, and a fourth AND gate 640. The PWM signal generator 620 generates a PWM signal S_{PWM} based on the control signal Sc. The PWM signal generator 620 comprises a comparator 623 and a ramp signal generator 625. The comparator 623 comprises a first input end for receiving the control signal Sc, a second input end coupled to the ramp signal generator 625, and an output end for outputting the PWM signal S_{PWM}. As shown in FIG. 6, the first input end of the comparator 623 is a positive input end and the second input end of the comparator 623 is a negative input end. In another embodiment, the first and second input ends of the comparator 623 can be the negative and positive input ends respectively. The ramp signal generator 625 is coupled to the second end of the comparator 623 and functions to provide a triangular wave signal or a sawtooth wave signal. The phase split circuit 650 extracts each odd pulse of the PWM signal S_{PWM} for generating the first push-pull signal S1 and extracts each even pulse of the PWM signal S_{PWM} for generating the second push-pull signal S2.

The first phase shift circuit 631 generates a driving signal Sshd1 by performing a phase shift operation on the rising and falling edges of each pulse of the first push-pull signal S1. The first AND gate 632 generates a driving signal S11 by performing an AND operation on the first push-pull signal S1 and the driving signal Sshd1. The first inverter 634 generates a first inverted signal S1b by performing an inverting operation on the first push-pull signal S1. The second phase shift circuit 633 generates a driving signal Sshd2 by performing a phase shift operation on the rising and falling edges of each pulse of the first inverted signal S1b. The second AND gate 635 generates a driving signal S12 by performing an AND operation on the first inverted signal S1b and the driving signal Sshd2.

The third phase shift circuit 636 generates a driving signal Sshd3 by performing a phase shift operation on the rising and falling edges of each pulse of the second push-pull signal S2. The third AND gate 637 generates a driving signal S21 by performing an AND operation on the second push-pull signal S2 and the driving signal Sshd3. The second inverter 639 generates a second inverted signal S2b by performing an inverting operation on the second push-pull signal S2. The fourth phase shift circuit 638 generates a driving signal Sshd4 by performing a phase shift operation on the rising and falling edges of each pulse of the second inverted signal S2b. The fourth AND gate 640 generates a driving signal S22 by performing an AND operation on the second inverted signal S2b and the driving signal Sshd4.

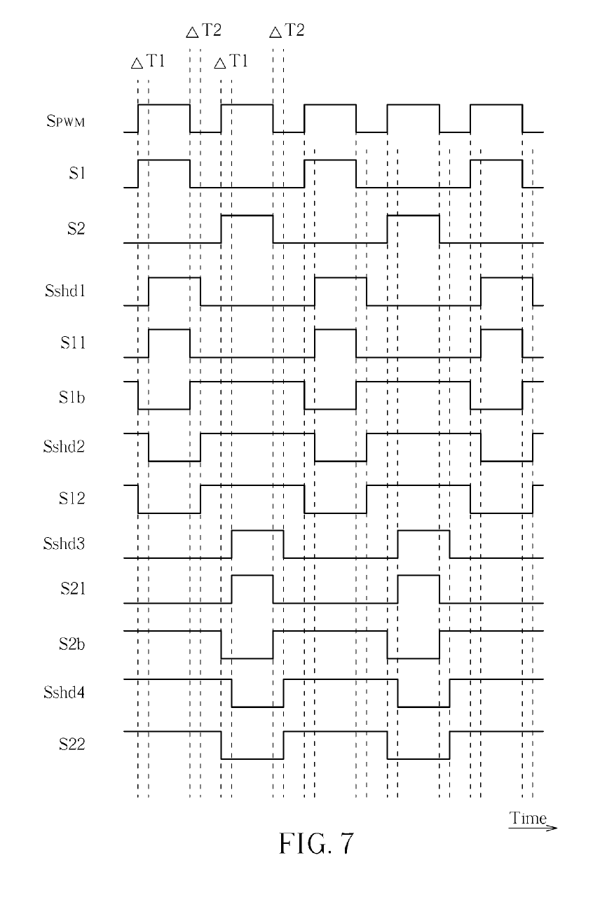

Please refer to FIG. 7, which shows the related signal waveforms regarding the operation of the driving signal generation circuit 610 in FIG. 6, having time along the abscissa. The signal waveforms in FIG. 7, from top to bottom, are the PWM signal S_{PWM}, the first push-pull signal S1, the second push-pull signal S2, the driving signal Sshd1, the driving signal S11, the first inverted signal S1b, the driving signal Sshd2, the driving signal S12, the driving signal Sshd3, the driving signal S21, the second inverted signal S2b, the driving signal Sshd4, and the driving signal S22. After the phase split circuit 650 performs a phase split operation on the PWM signal S_{PWM}, the first push-pull signal S1 and the second push-pull signal S2 are generated by respectively extracting the odd and even pulses of the PWM signal S_{PWM} as shown in FIG. 7.

After the first phase shift circuit 631 performs a phase shift operation on the first push-pull signal S1, the driving signal Sshd1 is generated through delaying the rising and falling edges of each pulse of the first push-pull signal S1 by a first phase shift time ΔT1 and a second phase shift time ΔT2 respectively, as shown in FIG. 7. After the first AND gate 632 performs an AND operation on the first push-pull signal S1 and the driving signal Sshd1, the driving signal S11 is generated. As shown in FIG. 7, the driving signal S11 is generated through delaying the rising edge of each pulse of the first push-pull signal S1 by the first phase shift time ΔT1 while retaining the falling edge of each pulse of the first push-pull signal S1.

After the first inverter 634 performs an inverting operation on the first push-pull signal S1, the first inverted signal S1 b is generated as shown in FIG. 7. After the second phase shift circuit 633 performs a phase shift operation on the first inverted signal S1b, the driving signal Sshd2 is generated through delaying the rising and falling edges of each pulse of the first inverted signal S1b by the second phase shift time ΔT2 and the first phase shift time ΔT1 respectively as shown in FIG. 7. After the second AND gate 635 performs an AND operation on the first inverted signal S1b and the driving signal Sshd2, the driving signal S12 is generated. As shown in FIG. 7, the driving signal S12 is generated through delaying the rising edge of each pulse of the first inverted signal S1b by the second phase shift time ΔT2 while retaining the falling edge of each pulse of the first inverted signal S1b.

After the third phase shift circuit 636 performs a phase shift operation on the second push-pull signal S2, the driving signal Sshd3 is generated through delaying the rising and falling edges of each pulse of the second push-pull signal S2 by the first phase shift time ΔT1 and the second phase shift time ΔT2 respectively as shown in FIG. 7. After the third AND gate 637 performs an AND operation on the second push-pull signal S2 and the driving signal Sshd3, the driving signal S21 is generated. As shown in FIG. 7, the driving signal S21 is generated through delaying the rising edge of each pulse of the second push-pull signal S2 by the first phase shift time ΔT1 while retaining the falling edge of each pulse of the second push-pull signal S2.

After the second inverter 639 performs an inverting operation on the second push-pull signal S2, the second inverted signal S2b is generated as shown in FIG. 7. After the fourth phase shift circuit 638 performs a phase shift operation on the second inverted signal S2b, the driving signal Sshd4 is generated through delaying the rising and falling edges of each pulse of the second inverted signal S2b by the second phase shift time ΔT2 and the first phase shift time ΔT1 respectively as shown in FIG. 7. After the fourth AND gate 640 performs an AND operation on the second inverted signal S2b and the driving signal Sshd4, the driving signal S22 is generated. As shown in FIG. 7, the driving signal S22 is generated through delaying the rising edge of each pulse of the second inverted signal S2b by the second phase shift time ΔT2 while retaining the falling edge of each pulse of the second inverted signal S2b.

As shown in FIG. 7, the duty cycle of the driving signal S12 and the duty cycle of the driving signal S11 are not overlapped, and the duty cycle of the driving signal S22 and the duty cycle of the driving signal S21 are not overlapped. The duty cycle of the driving signal S21 is substantially part of the duty cycle of the driving signal S12, and the duty cycle of the driving signal S11 is substantially part of the duty cycle of the driving signal S22. Furthermore, the lengths of the duty cycles of the driving signals S11 and S21 are the same, and the lengths of the duty cycles of the driving signals S12 and S22 are the same.

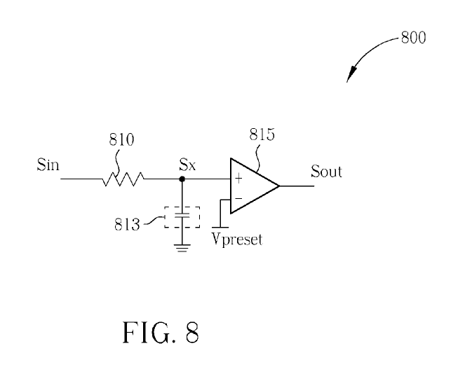

In one embodiment, the internal circuit structure of the related phase shift circuits 231, 431, 441, 631, 633, 636 and 638 in FIGS. 2, 4 and 6 can be designed as the phase shift circuit 800 shown in FIG. 8. Please refer to FIG. 8, which is a schematic circuit diagram showing a first embodiment of the phase shift circuit. As shown in FIG. 8, the phase shift circuit 800 comprises a resistor 810, a capacitor 813, and a comparator 815. The resistor 810 comprises a first end for receiving an input signal Sin, and a second end. The capacitor 813 comprises a first end coupled to the second end of the resistor 810, and a second end coupled to a ground. The comparator 815 comprises a first input end coupled to the first end of the capacitor 813, a second input end for receiving a preset voltage Vpreset, and an output end for outputting an output signal Sout. As shown in FIG. 8, the first input end of the comparator 815 is a positive input end and the second input end of the comparator 815 is a negative input end. In another embodiment, the first and second input ends of the comparator 815 can be the negative and positive input ends respectively.

The capacitor 813 together with the resistor 810 functions as a charging/discharging circuit for performing a charging/discharging operation based on the input signal Sin, and a charging/discharging signal Sx is generated at the first end of the capacitor 813. The comparator 815 compares the charging/discharging signal Sx with the preset voltage Vpreset for generating the output signal Sout.

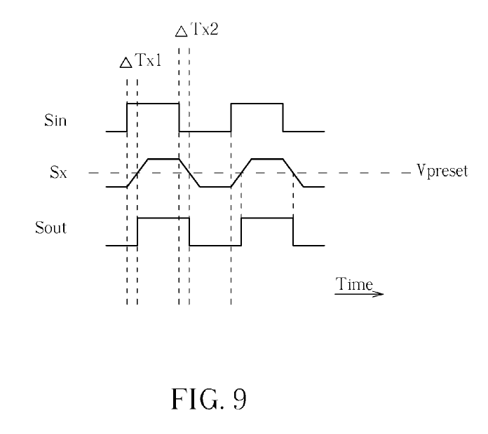

Please refer to FIG. 9, which shows the related signal waveforms regarding the operation of the phase shift circuit 800 in FIG. 8, having time along the abscissa. The signal waveforms in FIG. 9, from top to bottom, are the input signal Sin, the charging/discharging signal Sx, and the output signal Sout. After the input signal Sin goes through the charging/discharging operation of the resistor 810 and the capacitor 813, the charging/discharging signal Sx is generated as shown in FIG. 9. After comparing the charging/discharging signal Sx with the preset voltage Vpreset by the comparator 815, the output signal Sout is generated as shown in FIG. 9. That is, the phase shift circuit 800 generates the output signal Sout through delaying the rising and falling edges of each pulse of the input signal Sin by phase shift times ΔT×1 and ΔT×2 respectively as shown in FIG. 9.

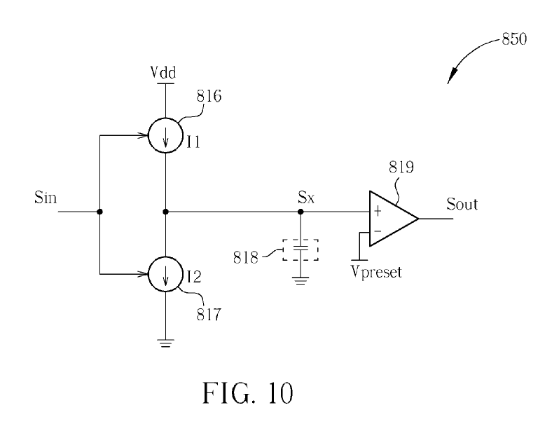

In another embodiment, the internal circuit structure of the related phase shift circuits 231, 431, 441, 631, 633, 636 and 638 in FIGS. 2, 4 and 6 can be designed as the phase shift circuit 850 shown in FIG. 10. Please refer to FIG. 10, which is a schematic circuit diagram showing a second embodiment of the phase shift circuit. As shown in FIG. 10, the phase shift circuit 850 comprises a first controllable current source 816, a second controllable current source 817, a capacitor 818, and a comparator 819. The first controllable current source 816 is coupled between a power supply having a supply voltage Vdd and the capacitor 818. The first controllable current source 816 is controlled by an input signal Sin and functions to provide a first current I1 based on the input signal Sin having a first voltage level. The second controllable current source 817 is coupled between a ground and the capacitor 818. The second controllable current source 817 is also controlled by the input signal Sin and functions to provide a second current 12 based on the input signal Sin having a second voltage level.

The capacitor 818 comprises a first end coupled to both the first controllable current source 816 and the second controllable current source 817, and a second end coupled to the ground. The capacitor 818 is utilized for performing a charging/discharging operation based on the first current I1 and the second current I2. The comparator 819 comprises a first input end coupled to the first end of the capacitor 818, a second input end for receiving a preset voltage Vpreset, and an output end for outputting an output signal Sout. As shown in FIG. 10, the first input end of the comparator 819 is a positive input end and the second input end of the comparator 819 is a negative input end. In another embodiment, the first and second input ends of the comparator 819 can be the negative and positive input ends respectively.

When the input signal Sin having the first voltage level is furnished, the first controllable current source 816 is enabled to provide the first current I1 for performing a charging operation on the capacitor 818. When the input signal Sin having the second voltage level is furnished, the second controllable current source 817 is enabled to provide the first current I2 for performing a discharging operation on the capacitor 818. Accordingly, a charging/discharging signal Sx is generated at the first end of the capacitor 818. The comparator 819 compares the charging/discharging signal Sx with the preset voltage Vpreset for generating the output signal Sout. The signal waveforms of the input signal Sin, the charging/discharging signal Sx and the output signal Sout regarding the operation of the phase shift circuit 850 are similar to the signal waveforms shown in FIG. 8, and for the sake of brevity, further discussion thereof is omitted.

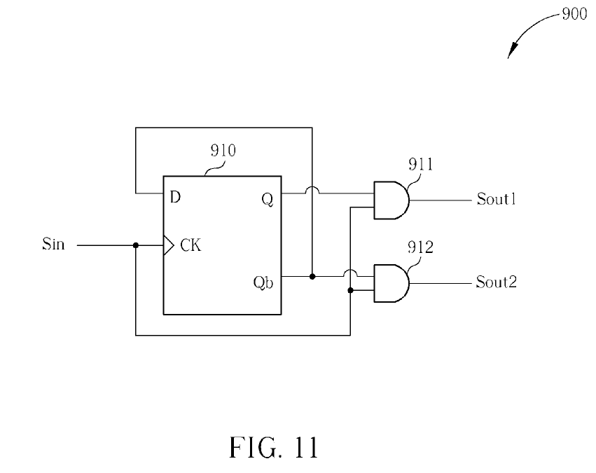

In one embodiment, the internal circuit structure of the related phase split circuits 250, 255, 450 and 650 in FIGS. 2, 4 and 6 can be designed as the phase split circuit 900 shown in FIG. 11. Please refer to FIG. 11, which is a schematic circuit diagram showing a first embodiment of the phase split circuit. As shown in FIG. 11, the phase split circuit 900 comprises a D flip-flop 910, a first AND gate 911 and a second AND gate 912. The D flip-flop 910 comprises a data input end D, a clock input end CK, a first output end Q and a second output end Qb. The signal at the second output end Qb is complementary to the signal at the first output end Q. The clock input end CK of the D flip-flop 910 is utilized for receiving an input signal Sin. The second output end Qb is coupled to the data input end D. The first AND gate 911 comprises a first input end coupled to the first output end Q of the D flip-flop 910, a second input end for receiving the input signal Sin, and an output end for outputting a first output signal Sout1. The second AND gate 912 comprises a first input end coupled to the second output end Qb of the D flip-flop 910, a second input end for receiving the input signal Sin, and an output end for outputting a second output signal Sout2.

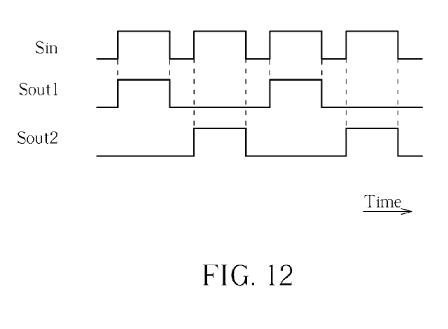

Please refer to FIG. 12, which shows the related signal waveforms regarding the operation of the phase split circuit 900 in FIG. 11, having time along the abscissa. The signal waveforms in FIG. 12, from top to bottom, are the input signal Sin, the first output signal Sout1, and the second output signal Sout2. As shown in FIG. 12, the first output signal Sout1 is generated by extracting each odd pulse of the input signal Sin, and the second output signal Sout2 is generated by extracting each even pulse of the input signal Sin. The is, each pulse of the first output signal Sout1 is corresponding to one odd pulse of the input signal Sin, and each pulse of the second output signal Sout2 is corresponding to one even pulse of the input signal Sin.

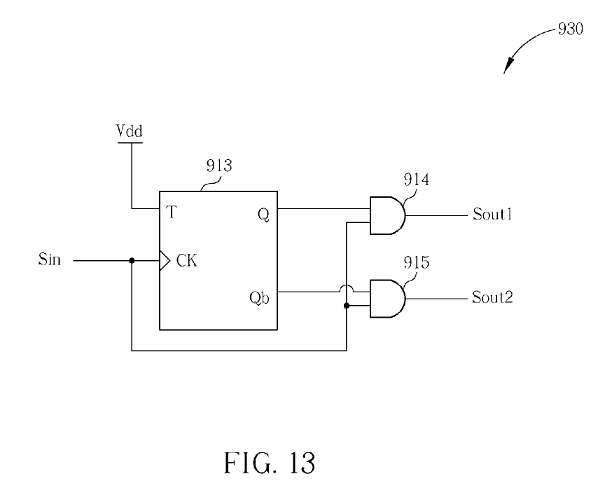

In another embodiment, the internal circuit structure of the related phase split circuits 250, 255, 450 and 650 in FIGS. 2, 4 and 6 can be designed as the phase split circuit 930 shown in FIG. 13. Please refer to FIG. 13, which is a schematic circuit diagram showing a second embodiment of the phase split circuit. As shown in FIG. 13, the phase split circuit 930 comprises a T flip-flop 913, a first AND gate 914 and a second AND gate 915. The T flip-flop 913 comprises a data input end T, a clock input end CK, a first output end Q and a second output end Qb. The clock input end CK of the T flip-flop 913 is utilized for receiving an input signal Sin. The data input end T of the T flip-flop 913 is utilized for receiving a supply voltage Vdd. The first AND gate 914 comprises a first input end coupled to the first output end Q of the T flip-flop 913, a second input end for receiving the input signal Sin, and an output end for outputting a first output signal Sout1. The second AND gate 915 comprises a first input end coupled to the second output end Qb of the T flip-flop 913, a second input end for receiving the input signal Sin, and an output end for outputting a second output signal Sout2. The signal waveforms of the input signal Sin, the first output signal Sout1 and the second output signal Sout2 regarding the operation of the phase split circuit 930 are identical to the signal waveforms shown in FIG. 12, and for the sake of brevity, further discussion thereof is omitted.

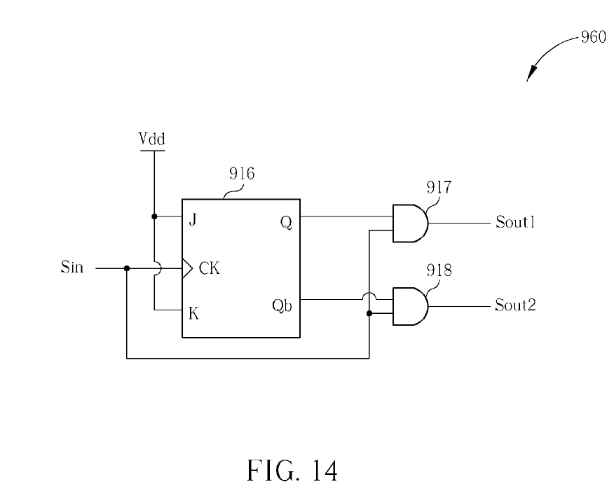

Furthermore, in another embodiment, the internal circuit structure of the related phase split circuits 250, 255, 450 and 650 in FIGS. 2, 4 and 6 can be designed as the phase split circuit 960 shown in FIG. 14. Please refer to FIG. 14, which is a schematic circuit diagram showing a third embodiment of the phase split circuit. As shown in FIG. 14, the phase split circuit 960 comprises a JK flip-flop 916, a first AND gate 917 and a second AND gate 918. The JK flip-flop 916 comprises a first data input end J, a second data input end K, a clock input end CK, a first output end Q and a second output end Qb. The clock input end CK of the JK flip-flop 916 is utilized for receiving an input signal Sin. The first data input end J and the second data input end K of the T flip-flop 913 are utilized for receiving a supply voltage Vdd. The first AND gate 917 comprises a first input end coupled to the first output end Q of the JK flip-flop 916, a second input end for receiving the input signal Sin, and an output end for outputting a first output signal Sout1. The second AND gate 918 comprises a first input end coupled to the second output end Qb of the JK flip-flop 916, a second input end for receiving the input signal Sin, and an output end for outputting a second output signal Sout2. The signal waveforms of the input signal Sin, the first output signal Sout1 and the second output signal Sout2 regarding the operation of the phase split circuit 960 are identical to the signal waveforms shown in FIG. 12, and for the sake of brevity, further discussion thereof is omitted.

Compared to the prior-art driving signal generation circuit, the couple capacitors are not included in the driving signal generation circuit of the present invention, and the capacitor in the phase shift circuit is utilized for charging/discharging rather than for coupling. Accordingly, the driving signal generation circuit of the present invention is working without the aforementioned problems regarding initial value setting and circuit transient response. In other words, after power on, the driving signal generation circuit of the present invention is capable of working properly in a real time. Also, the driving signal generation circuit of the present invention can provide accurate driving signals to a full-bridge inverter for outputting an AC signal having exactly balanced positive and negative half-periods. Therefore, the DC component of the AC signal is substantially null, and the block capacitor is not required to be installed for performing a DC blocking operation on the AC signal. Besides, the driving signal generation circuit of the present invention drives a full-bridge inverter without the aid of resistive buffer components, and therefore the driving ability of the full-bridge inverter is not limited by any resistive buffer component.

The present invention is by no means limited to the embodiments as described above by referring to the accompanying drawings, which may be modified and altered in a variety of different ways without departing from the scope of the present invention. Thus, it should be understood by those skilled in the art that various modifications, combinations, sub-combinations and alternations might occur depending on design requirements and other factors insofar as they are within the scope of the appended claims or the equivalents thereof.

What is claimed is:

1. A system comprising:
a driving signal generation circuit for receiving a pulse width modulation (PWM) signal, the driving signal generation circuit generating a first driving signal based on the PWM signal, wherein a duty cycle of the first driving signal is generated by means of firstly performing a phase shift operation and secondly performing a phase split operation regarding the PWM signal.

2. The system of claim 1, wherein the driving signal generation circuit further outputs a second driving signal based on the PWM signal, wherein a duty cycle of the second driving signal and the duty cycle of the first driving signal are not overlapped, and a length of the duty cycle of the second driving signal is the same as a length of the duty cycle of the first driving signal.

3. The system of claim 2, wherein the driving signal generation circuit further outputs a third driving signal and a fourth driving signal based on the PWM signal, wherein a duty cycle of the third driving signal is part of the duty cycle of the first driving signal, a duty cycle of the fourth driving signal is part of the duty cycle of the second driving signal, and a length of the duty cycle of the third driving signal is the same as a length of the duty cycle of the fourth driving signal.

4. The system of claim 3, wherein the first driving signal and the second driving signal are furnished to a first P-channel metal oxide semiconductor (PMOS) field effect transistor and a second PMOS field effect transistor respectively, and the third driving signal and the fourth driving signal are furnished to a first NMOS field effect transistor and a second NMOS field effect transistor respectively.

5. A system comprising:
a driving signal generation circuit for receiving a PWM signal, the driving signal generation circuit generating a first driving signal based on the PWM signal, wherein a duty cycle of the first driving signal is generated by means of firstly performing a phase split operation and secondly performing a phase shift operation regarding the PWM signal.

6. The system of claim 5, wherein the driving signal generation circuit further outputs a second driving signal based on the PWM signal, wherein a duty cycle of the second driving signal is part of the duty cycle of the first driving signal.

7. The system of claim 5, wherein the driving signal generation circuit further outputs a second driving signal, a third driving signal and a fourth driving signal based on the PWM signal, wherein a duty cycle of the second driving signal is part of the duty cycle of the first driving signal, a duty cycle of the third driving signal and the duty cycle of the first driving signal are not overlapped, a duty cycle of the fourth driving signal is part of the duty cycle of the third driving signal, a length of the duty cycle of the first driving signal is the same as a length of the duty cycle of the third driving signal, and a length of the duty cycle of the second driving signal is the same as a length of the duty cycle of the fourth driving signal.

8. The system of claim 7, wherein the first driving signal and the third driving signal are furnished to a first PMOS field effect transistor and a second PMOS field effect transistor respectively, and the second driving signal and the fourth driving signal are furnished to a first NMOS field effect transistor and a second NMOS field effect transistor respectively.

9. The system of claim 5, wherein the driving signal generation circuit further outputs a second driving signal based on the PWM signal, wherein a duty cycle of the second driving signal and the duty cycle of the first driving signal are not overlapped.

10. The system of claim 9, wherein the driving signal generation circuit further outputs a third driving signal and a fourth driving signal based on the PWM signal, wherein a duty cycle of the third driving signal is part of the duty cycle of the second driving signal, a duty cycle of the fourth driving signal and the duty cycle of the third driving signal are not overlapped, a length of the duty cycle of the first driving signal is the same as a length of the duty cycle of the third driving signal, and a length of the duty cycle of the second driving signal is the same as a length of the duty cycle of the fourth driving signal.

11. The system of claim 10, wherein the first driving signal, the second driving signal, the third driving signal and the fourth driving signal are furnished to a first NMOS field effect transistor, a second NMOS field effect transistor, a third NMOS field effect transistor and a fourth NMOS field effect transistor respectively.

12. A driving signal generation circuit comprising:
a transforming circuit for generating a first transformed signal by essentially performing a phase shift operation on a PWM signal; and
a first phase split circuit for generating a first driving signal and a second driving signal by respectively extracting a first pulse and a second pulse of the first transformed signal.

13. The driving signal generation circuit of claim 12, wherein the transforming circuit performs a phase shift operation on a first edge of the PWM signal for generating the first transformed signal, and the transforming circuit further performs a phase shift operation on a second edge of the PWM signal for generating a second transformed signal.

14. The driving signal generation circuit of claim 13, further comprising:
a second phase split circuit for generating a third driving signal and a fourth driving signal by respectively extracting a third pulse and a fourth pulse of the second transformed signal.

15. A driving signal generation circuit comprising:
a phase split circuit for generating a first push-pull signal by extracting a first pulse of a PWM signal; and
a first transforming circuit for generating a first driving signal by essentially performing a phase shift operation on the first push-pull signal.

16. The driving signal generation circuit of claim 15, wherein the first transforming circuit comprises:
a first phase shift circuit for generating a first phase shift signal by performing a phase shift operation on the first push-pull signal; and
a first OR gate for generating the first driving signal by performing an OR operation on the first push-pull signal and the first phase shift signal.

17. The driving signal generation circuit of claim 16, wherein the first transforming circuit further comprises:
a first AND gate for generating a second driving signal by performing an AND operation on the first push-pull signal and the first phase shift signal.

18. The driving signal generation circuit of claim 15, wherein the phase split circuit further generates a second push-pull signal by extracting a second pulse of the PWM signal, and the driving signal generation circuit further comprises a second transforming circuit for generating a third driving signal and a fourth driving signal by essentially performing a phase shift operation on the second push-pull signal.

19. The driving signal generation circuit of claim 15, wherein the first transforming circuit comprises:
a first phase shift circuit for generating a first phase shift signal by performing a phase shift operation on the first push-pull signal; and
a first AND gate for generating the first driving signal by performing an AND operation on the first push-pull signal and the first phase shift signal.

20. The driving signal generation circuit of claim 19, wherein the first transforming circuit further comprises:
a first inverter for generating a first inverted signal by performing an inverting operation on the first push-pull signal;
a second phase shift circuit for generating a second phase shift signal by performing a phase shift operation on the inverted signal; and
a second AND gate for generating a second driving signal by performing an AND operation on the inverted signal and the second phase shift signal.

21. The driving signal generation circuit of claim 20, further comprising:
a PWM signal generator for generating the PWM signal; and
a network circuit comprising a plurality of switches, the switches controlling an electrical connection between a power source and a load based on the driving signals.
